(19) United States
(12) Patent Application Publication
(10) Pub. No.: US 2024/0312793 A1
(43) Pub. Date: Sep. 19, 2024

(54) Thermal Neutron Transmutation Doped Gallium Oxide Semiconductor

(71) Applicants: Marko J. Tadjer, Vienna, VA (US); Travis J. Anderson, Alexandria, VA (US); Francis J. Kub, Arnold, MD (US); Alan G. Jacobs, Rockville, MD (US); Noel A. Guardala, Columbia, MD (US); John D. Brockman, Columbia, MO (US); John M. Gahl, Columbia, MO (US)

(72) Inventors: Marko J. Tadjer, Vienna, VA (US); Travis J. Anderson, Alexandria, VA (US); Francis J. Kub, Arnold, MD (US); Alan G. Jacobs, Rockville, MD (US); Noel A. Guardala, Columbia, MD (US); John D. Brockman, Columbia, MO (US); John M. Gahl, Columbia, MO (US)

(21) Appl. No.: 18/606,024

(22) Filed: Mar. 15, 2024

Related U.S. Application Data
(60) Provisional application No. 63/452,785, filed on Mar. 17, 2023.

(51) Int. Cl. H01L 21/423; C01G 15/00; C30B 29/16; C30B 33/04; H01L 29/24

(52) U.S. Cl. CPC H01L 21/423; C01G 15/00; C30B 29/16; C30B 33/04; H01L 29/24; C01P 2002/54; C01P 2006/40; C01P 2006/88

(57) ABSTRACT

A germanium (Ge)-doped gallium oxide (Ga²O³) semiconductor material and method of making are provided. In embodiments, a method of making the Ge-doped Ga²O³ semiconductor material includes: subjecting a Ga₂O₃ semiconductor material to neutron irradiation comprising a higher thermal neutron content than fast neutron content, thereby producing a Ge-doped Ga₂O₃ semiconductor material; and annealing the Ge-doped Ga₂O₃ semiconductor material at a temperature of at least 700° C. in an atmosphere of nitrogen gas, thereby generating an electrically conductive n-type Ge-doped Ga₂O₃ semiconductor material.

### CROSS-REFERENCE TO RELATED APPLICATIONS

This Application is a Nonprovisional of, and claims the benefit of priority under 35 U.S.C. § 119 based on, U.S. Provisional Patent Application No. 63/452,785 filed Mar. 17, 2023. The Provisional Application and all references cited herein are hereby incorporated by reference into the present disclosure in their entirety.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case No. 211473-US2.

### BACKGROUND OF THE INVENTION

Aspects of the present invention relate generally to doping semiconductor materials and, more particularly, to doping gallium oxide (Ga₂O₃) using thermal neutron transmutation.

Monoclinic (β) Ga₂O₃ semiconductor technology has experienced rapid growth in recent years. After initial growth demonstrations in Japan, commercial growth of up to 100 mm diameter Ga₂O₃ substrates has been implemented using melt-growth techniques such as edge-defined, film-fed growth (EFG), float-zone, and vertical Bridgman. Commercial Ga₂O₃ substrates are doped to be semi-insulating by either iron (Fe) or magnesium (Mg) compensation, or are doped to be highly-conductive by either silicon (Si) or tin (Sn) doping. Domestic production of semi-insulating Ga₂O₃ substrates has been scaled up to 2-inch using Czochralski and EFG techniques. On the epitaxial side, Ge doping of molecular beam epitaxy (MBE)-Ga₂O₃ and Ge-doped metalorganic chemical vapor deposition (MOCVD)-Ga₂O₃ have been reported. Ge-doped Ga₂O₃ transistors have been reported as well. However, Ge-doped Ga₂O₃ semiconductor substrates have not been demonstrated.

Neutron transmutation doping (NTD) is a well-established technique for commercial production of uniformly-doped silicon (Si) boules with a minimum of induced displacement damage at low neutron energies. In general, NTD is a doping technique, whereby silicon is irradiated in a thermal neutron flux for the purpose of creating a uniformly doped semiconductor material. Different semiconductor materials respond differently to NTD. In one example, an attempt to dope Ga₂O₃ with Ge via NTD resulted in a highly resistive crystal whose conductivity could not be measured, suggesting that Ge donors are strongly compensated by neutron-induced defects and Zn acceptors from low-probability Ga decay in the substrate. Therefore, there remains a need to develop new NTD techniques to generate an electrically conductive semiconductor Ga₂O₃ substrate.

### SUMMARY OF THE INVENTION

In a first aspect of the invention, there is a method of making a germanium (Ge)-doped gallium oxide (Ga₂O₃) semiconductor material, including: subjecting a Ga₂O₃ semiconductor material to neutron irradiation comprising a higher thermal neutron content than fast neutron content, thereby producing a Ge-doped Ga₂O₃ semiconductor material; and annealing the Ge-doped Ga₂O₃ semiconductor material at a temperature of at least 700° C. in an atmosphere of nitrogen gas, thereby generating an electrically conductive n-type Ge-doped Ga₂O₃ semiconductor material.

In another aspect of the invention, there is an electrically conductive n-type germanium (Ge)-doped gallium oxide (Ga²O³) semiconductor wafer or boule having an electrical resistivity of between 0.05 and 10¹⁰ Ohm·cm. In implementations, the electrically conductive n-type Ge-doped Ga₂O₃ semiconductor wafer or boule is formed by subjecting a Ga₂O₃ semiconductor wafer or boule to neutron irradiation comprising a higher thermal neutron content than fast neutron content, thereby producing a Ge-doped Ga₂O₃ semiconductor wafer or boule; and annealing the Ge-doped Ga₂O₃ semiconductor wafer or boule at a temperature of at least 700° C. in an atmosphere of nitrogen gas, thereby generating the electrically conductive n-type Ge-doped Ga₂O₃ semiconductor wafer or boule.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 shows a flowchart of an exemplary method in accordance with aspects of the present invention.

FIG. 2 shows a diagram of the exemplary method of FIG. 1.

### DETAILED DESCRIPTION

Aspects of the present invention relate generally to doping semiconductor materials and, more particularly, to doping gallium oxide (Ga₂O₃) using thermal neutron transmutation. In embodiments, a method is provided for generating a germanium (Ge)-doped Ga₂O₃ semiconductor substrate. Implementations of the invention produce controllably-low-doped β-Ga₂O₃ wafers for high-voltage power applications.

Advantageously, implementations of the invention reduce the generation of defects in a Ga₂O₃ substrate during neutron transmutation doping (NTD) by utilizing neutron irradiation having a high thermal neutron to fast neutron ratio followed by a high-temperature annealing process. Embodiments of the invention result in an electrically conductive Ga₂O₃ substrate uniformly doped with Ge.

In implementations, thermal neutron reactions with the stable isotopes of gallium-69 (Ga-69) and gallium-71 (Ga-71) in a Ga₂O₃ substrate result in neutron capture to produce the unstable isotopes gallium-70 (Ga-70) and gallium-72 (Ga-72), which decay into respective stable germanium-70 (Ge-70) and germanium-72 (Ge-72) shallow donors. When the donor concentration (Np) is higher than the total concentration of intentional acceptors (e.g., N, Fe, Zn, etc.) and unintentional acceptors (e.g., V_{Ga}) acceptors (collectively N_{A}), a net excess electron concentration n (n=N_{D}−N_{A}) will result in an n-type doped semiconductor.

Unlike previous attempts to dope costly GaN boules, embodiments of the invention exploit the availability of affordable melt-grown boules of Ga₂O₃ as a viable route to produce large-area, uniformly doped substrates of any orientation for vertical power device applications. Currently, conductive Ga₂O₃ substrates doped via silicon (Si) or tin (Sn) donors can be doped n-type at levels of no less than 10¹⁷ electrons/cm³, necessitating the growth of thick, low-doped (<10¹⁶ cm⁻³) epitaxial layers for vertical power devices. The growth of thick epitaxial layers will inevitably results in the evolution of point and extended defects towards the epitaxial layer surface, leading to difficulty in maintaining high crystal quality epitaxial β-Ga₂O₃ beyond a few micrometers. Advantageously, embodiments of the invention result in n-type Ga₂O₃ substrates doped in the 10¹⁵-10¹⁶ electrons/cm³ range, similar to that of Si substrates. Such substrates will greatly reduce the necessity of tens of micrometers thick epitaxial layers and greatly increase the relevance of Ga₂O₃ for power electronics applications. Additionally, unlike neutron irradiation of GaN, implementations of the present invention do not result in a semiconductor material including residual radioactive carbon-14 (C-14).

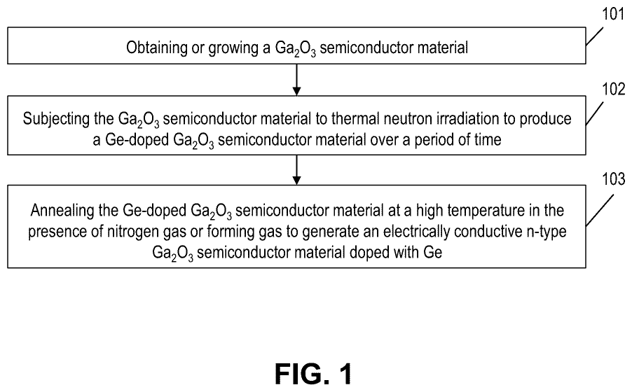

FIG. 1 shows a flowchart of an exemplary method in accordance with aspects of the present invention. In embodiments, at step 101, a method of the invention includes obtaining or growing a Ga₂O₃ semiconductor substrate. In implementations, a β-Ga₂O₃ semiconductor substrate is grown utilizing a known method, such as the Float Zone, Czochralski, Vertical Bridgman and edge-defined film-fed growth (EFG) methods.

Some growth methods have been shown to result in a Ga₂O₃ substrate including iridium (Ir). For example, Ir is a common unintentional impurity in Ga₂O₃ crystals synthesized via EFG and Czochralski techniques relying on the use of an Ir crucible. Upon neutron irradiation, the radioisotope Ir-192 will be produced via neutron capture. With a half-life of 73 days for the gamma rays resulting, Ir-192 is a strong gamma emitter and is thus undesirable from an electronic device safety perspective. Accordingly, in embodiments, the Ga₂O₃ semiconductor substrate is grown utilizing an iridium-free method to produce an iridium-free Ga₂O₃ semiconductor substrate. For example, the Ga₂O₃ semiconductor substrate may be grown by the float-zone (zone melting) method or vertical Bridgman method, another crucible-free or non-Ir crucible method, or another EFG or CZ technique where Ir incorporation in the Ga₂O₃ crystal is suppressed.

With continued reference to FIG. 1, at step 102 implementations of the invention include subjecting the Ga₂O₃ semiconductor substrate of step 101 to a primarily thermal neutron flux irradiation with a low flux of fast neutrons to produce a Ge-doped Ga₂O₃ semiconductor substrate over a period of time. In embodiments, the irradiation comprises a thermal neutron energy of less than or equal to 0.5 eV, or less than or equal to 0.025 eV, to encompass the slow, thermal, epithermal and cadmium neutron energy range.

In aspects of the invention, the period of time for step 102 to enable decay of Ga-70 and Ga-72 to Ge-70 and Ge-72, respectively, is nominally proportional to the decay half-life for the two isotopes, 21.1 minutes for Ga-70 and 14.1 hours for Ga-72. In embodiments, this period of time is a nominal quarantine period of about two weeks prior to material release from the reactor. In embodiments, the thermal neutron irradiation comprises a thermal neutron to fast neutron ratio of at least 25:1. In implementations, the thermal to fast neutron ratio can vary from 1:1 to higher than 25:1 depending on reactor placement, filtering, neutron energy spectrum, etc., however, a highest ratio is desirable. In implementations, a neutron moderator is utilized to thermalize neutron irradiation to the Ga₂O₃ semiconductor substrate resulting in the thermalization (i.e., reducing neutron energy) of any non-thermal (e.g., fast, epithermal, etc.) neutron irradiation. In general, a neutron moderator is a medium(s) that reduces the speed of fast neutrons, ideally without capturing any, leaving them as thermal neutrons. Upon thermal neutron irradiation, Ga-69 and Ga-71 isotopes in the Ga₂O₃ semiconductor substrate transmute to the unstable isotopes Ga-70 and Ga-72, respectively. In turn, the unstable isotopes Ga-70 and Ga-72 decay over time to produce stable isotopes Ge-70 and Ge-72, respectively. Thus, the end-product of the thermal neutron irradiation of the Ga₂O₃ semiconductor substrate in accordance with embodiments of the invention results is a Ge-doped Ga₂O₃ semiconductor substrate.

In implementation, the Ga₂O₃ semiconductor substrate is irradiated for an appropriate period of time for the conditions (e.g., 82 hours when irradiating a large piece of Ga₂O₃ within a container in a neutron flux of 5×10¹³ neutrons per cubic centimeters per second (n/cm²/s)). One of ordinary skill in the art could select an appropriate time period and flux for a particular size of Ga₂O₃ semiconductor substrate, and the present invention is not intended to be limited to a particular NTD time or neutron flux conditions. In embodiments, the Ga₂O₃ semiconductor substrate is in the form of a wafer of boule (bulk crystal) having a size of between a 1 cm² diameter and a 6 inch diameter. In the case of boules, the final product may be sliced into wafers. Various reactors may be utilized to implement step 102. One example of a reactor that may be utilized to provide thermal neutron irradiation in accordance with methods of the present invention is the University of Missouri Research Reactor (MURR). It should be understood that other reactors with high thermal neutron flux and low fast neutron flux are also capable of performing neutron transmutation doping.

In NTD, the number of neutron captures per unit volume, N, is described by N=N_{T}σ_{c}Φ, where N_{T} is the number of target nuclei per unit volume, σ_{c} is the capture cross section with units of cm², and Φ is the neutron fluence, n/cm². The cross section represents the probability of interaction between the neutron and the nucleus. Neutron capture reactions occur at higher rates with low energy neutrons because the lower velocity allows greater interaction with the target nuclei. The capture cross section is inversely proportional to the neutron velocity at low energies. Reactor neutrons are parameterized into three groups based on energy. Fast neutrons have an energy greater than 100 kiloelectron volts (keV), epithermal neutrons have an energy between 0.5 electron volts (eV) and 100 keV, and thermal neutrons have an energy less than 0.5 eV. In implementations, NTD of Ga₂O₃ will occur when Ga-69 and Ga-71 undergo neutron capture reactions with thermal neutrons to produce unstable Ga-70 and Ga-72, respectively. The unstable isotopes Ga-70 and Ga-72 beta decay over a period of time to produce respective stable isotopes Ge-70 and Ge-72, thereby producing the Ge-doped Ga₂O₃ wafer or boule. The period of time for the unstable isotopes Ga-70 and Ga-72 to decay to produce the Ge-doped Ga₂O₃ wafer or boule (bulk crystal) is based on the half-life of Ga-72. Ga-70 and Ga-72 have half-lives of 21.1 minutes and 14.1 hours, respectively. Fast neutrons are unlikely to be captured, but cause knock-on damage through elastic scatter.

Thermal neutron irradiation is known to cause defects in Ga₂O₃. In order to address these defects, at step 103, implementations of the invention include annealing the Ge-doped Ga₂O₃ semiconductor substrate product of step 102 to obtain an electrically conductive Ge-doped Ga₂O₃ semiconductor substrate. In aspects of the invention, the electrically conductive Ge-doped Ga₂O₃ semiconductor substrate includes a Ge concentration of between 10¹³ and 10¹⁸ Ge per cubic centimeter (Ge/cm³). In certain embodiments, the electrically conductive Ge-doped Ga₂O₃ semiconductor substrate includes a Ge concentration of between 10¹⁶ and 10¹⁸ Ge/cm³. In aspects of the invention the electrically conductive neutron transmutation Ge-doped Ga₂O₃ semiconductor substrate has an electrical resistivity of between 0.05 and 10¹⁰ Ohm·cm.

In implementations, the Ge-doped Ga₂O₃ semiconductor substrate product of step 102 is subjected to a high-temperature annealing process in an atmosphere of nitrogen gas (e.g., pure nitrogen gas) or forming gas. Forming gas is a mixture of hydrogen gas (H₂) and nitrogen gas (N₂), and is sometimes referred to as dissociated ammonia atmosphere. Forming gas typically has a ratio of H₂ to N₂ of 5:95%. In implementations, the annealing temperature is greater or equal to 700° C. In some embodiments, the annealing temperature is between 700° C. and 1600° C.

In accordance with embodiments of the invention, the Ge-doped Ga₂O₃ semiconductor substrate is annealed for a time period of between 10 seconds and 72 hours. In implementations, the annealing occurs in a chamber pressurized to between vacuum and atmospheric pressure. In embodiments, the annealing at step 103 may be implemented as a series of rapid heating and cooling pulses (e.g., up to ˜600 K/s) at moderate pressures (e.g., ˜10-100 bar) via multicycle rapid thermal annealing (MRTA) to access intermediate (˜1250° C.) and high (1600° C.) states. In implementations, the MRTA occurs at a pressure near 35 bar, and with temperature pulses between 500 C and 1500 C at 300K/s. In aspects of the invention, step 103 includes a substep of capping a surface of the Ge-doped Ga₂O₃ semiconductor substrate with a protective layer (e.g., silicon nitride, silicon oxide, aluminum nitride, aluminum oxide, or other oxides or nitrides) during annealing to protect against surface reconstruction.

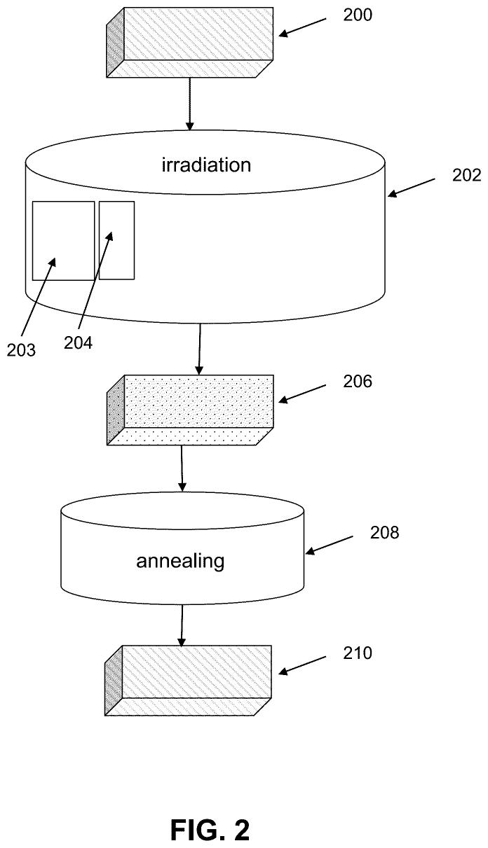

FIG. 2 shows a diagram of the exemplary method of FIG. 1. Specifically, a Ga₂O₃ semiconductor wafer or boule material 200 is shown prior to neutron irradiation. In embodiments, the Ga₂O₃ semiconductor wafer or boule material 200 is placed within a reactor chamber 202 and exposed to thermal neutron radiation from a neutron source 203 and moderator 204. As noted above, exposure to thermal neutron radiation transforms stable Ga isotopes to unstable isotopes, which in turn decay to stable Ge isotopes within the Ga₂O₃ semiconductor wafer or boule over a period of time to produce a Ge-doped Ga₂O₃ semiconductor wafer or boule 206 having defects due to the neutron irradiation. The Ge-doped Ga₂O₃ semiconductor wafer or boule 206 is then subjected to annealing in an oven 208 in accordance with embodiments of the invention to reduce defects and produce a final electrically conductive n-type Ge-doped Ga₂O₃ semiconductor wafer or boule 210.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of making a germanium (Ge)-doped gallium oxide (Ga₂O₃) semiconductor material, comprising:
subjecting a Ga₂O₃ semiconductor material to neutron irradiation comprising a higher thermal neutron content than fast neutron content, thereby producing a Ge-doped Ga₂O₃ semiconductor material; and
annealing the Ge-doped Ga₂O₃ semiconductor material at a temperature of at least 700° C. in an atmosphere of nitrogen gas, thereby generating an electrically conductive n-type Ge-doped Ga₂O₃ semiconductor material.

2. The method of claim 1, wherein the neutron irradiation is performed using a thermal neutron to fast neutron ratio of at least 25:1.

3. The method of claim 1, wherein the neutron irradiation has an energy of less than or equal to 0.5 electron volts (eV).

4. The method of claim 1, wherein the neutron irradiation has an energy of less than or equal to 0.025 electron volts (eV).

5. The method of claim 1, wherein the n-type Ge-doped Ga₂O₃ semiconductor material has a Ge concentration between 10¹³ Ge atoms/cm³ and 10¹⁸ Ge atoms/cm³.

6. The method of claim 1, wherein the n-type Ge-doped Ga₂O₃ semiconductor material has a Ge concentration between 10¹⁶ Ge atoms/cm³ and 10¹⁸ Ge atoms/cm³.

7. The method of claim 1, wherein the n-type Ge-doped Ga₂O₃ semiconductor material has a resistivity of between 0.05 and 10¹⁰ Ohm·cm.

8. The method of claim 1, further comprising capping a surface of the Ge-doped Ga₂O₃ semiconductor material with a protective material prior to the annealing to protect against surface reconstruction during the annealing.

9. The method of claim 1, wherein the annealing is performed via multicycle rapid thermal annealing (MRTA) using a series of rapid heating and cooling pulses.

10. The method of claim 1, wherein the Ga₂O₃ semiconductor material is free of iridium (Ir).

11. The method of claim 1, further comprising growing the Ga₂O₃ semiconductor material.

12. The method of claim 1, wherein the neutron irradiation transmutes Ga-69 isotopes and Ga-71 isotopes in the Ga₂O₃ semiconductor wafer or boule to respective unstable isotopes Ga-70 and Ga-72, wherein the unstable isotopes Ga-70 and Ga-72 decay over a period of time to produce respective stable isotopes Ge-70 and Ge-72, thereby producing the Ge-doped Ga₂O₃ material in the form of a wafer of boule, and wherein the period of time is based on the half-life of Ga-72.

13. An electrically conductive n-type germanium (Ge)-doped gallium oxide (Ga₂O₃) semiconductor wafer or boule having an electrical resistivity of between 0.05 and 10¹⁰ Ohm·cm.

14. The electrically conductive n-type Ge-doped Ga₂O₃ wafer or boule of claim 13, wherein the conductive n-type Ge-doped Ga₂O₃ semiconductor wafer or boule is free of iridium (Ir).

15. The electrically conductive n-type Ge-doped Ga₂O₃ wafer or boule of claim 13, further comprising a Ge concentration between 10¹³ Ge atoms/cm³ and 10¹⁸ Ge atoms/cm³.

16. The electrically conductive n-type Ge-doped Ga₂O₃ wafer or boule of claim 13, further comprising a Ge concentration between 10¹⁶ Ge atoms/cm³ and 10¹⁸ Ge atoms/cm³.

17. The electrically conductive n-type Ge-doped Ga₂O₃ semiconductor wafer or boule of claim 13, formed by:
subjecting a Ga₂O₃ semiconductor wafer or boule to neutron irradiation comprising a higher thermal neutron content than fast neutron content, thereby producing a Ge-doped Ga₂O₃ semiconductor wafer or boule; and
annealing the Ge-doped Ga₂O₃ semiconductor wafer or boule at a temperature of at least 700° C. in an atmosphere of nitrogen gas, thereby generating the electrically conductive n-type Ge-doped Ga₂O₃ semiconductor wafer or boule.

18. The electrically conductive n-type Ge-doped Ga₂O₃ semiconductor wafer or boule of claim 17, wherein the neutron irradiation is performed using a thermal neutron to fast neutron ratio of at least 25:1.

19. The electrically conductive n-type Ge-doped Ga₂O₃ semiconductor wafer or boule of claim 17, wherein the annealing is performed via multicycle rapid thermal annealing (MRTA) using a series of rapid heating and cooling pulses.

20. The electrically conductive n-type Ge-doped Ga₂O₃ semiconductor wafer or boule of claim 17, wherein the neutron irradiation transmutes Ga-69 isotopes and Ga-71 isotopes in the Ga₂O₃ semiconductor wafer or boule to respective unstable isotopes Ga-70 and Ga-72, and wherein the unstable isotopes Ga-70 and Ga-72 decay over a period of time to produce respective stable isotopes Ge-70 and Ge-72, thereby producing the Ge-doped Ga₂O₃ wafer or boule, and wherein the period of time is based on the half-life of Ga-72.
